(19) United States
(12) Patent Application Publication
(10) Pub. No.: US 2014/0102368 A1
(43) Pub. Date: Apr. 17, 2014

(54) GAS ISOLATION CHAMBER AND PLASMA DEPOSITION APPARATUS THEREOF

(71) Applicant: Institute of Nuclear Energy Research Atomic Energy Council, Executive Yuan, Taoyuan County (TW)

(72) Inventors: CHENG-CHANG HSIEH, Chiayi City (TW); DENG-LAIN LIN, TAOYUAN COUNTY (TW); CHING-PEI TSENG, TAOYUAN COUNTY (TW); JIN-YU WU, TAOYUAN COUNTY (TW); JIUN-SHEN CHEN, TAOYUAN COUNTY (TW); CHI-FONG AI, TAOYUAN COUNTY (TW)

(21) Appl. No.: 13/906,462

(22) Filed: May 31, 2013

(30) Foreign Application Priority Data
Oct. 12, 2012 (TW) 101137743

(51) Int. Cl. C23C 16/44

(52) U.S. Cl. CPC C23C 16/4409
USPC 118/723 R; 118/733

(57) ABSTRACT

A gas isolation chamber comprises a vacuum chamber, a first body module, a second body module and a first temperature modulator. The vacuum chamber comprises a first chamber part, a second chamber part and at least one first gas valve unit. The first body module is disposed on the inner wall of the first chamber part and has a first gas hole corresponding to the position of the first gas valve unit. The first gas hole is connected to the first gas valve unit. The second body module is disposed on the inner wall of the second chamber part such that a slit channel can be formed between the second and the first body modules. The first temperature modulator is disposed in the first body module. The gas isolation chamber is further combined with the vacuum film process chambers to form a plasma deposition apparatus for proceeding continuous deposition process.

### FIELD OF THE INVENTION

The present invention relates to gas isolation and film deposition technologies, and more particularly, to a gas isolation chamber and a plasma deposition apparatus using the same.

### BACKGROUND OF THE INVENTION

Comparing with those conventional glass substrates and silicon substrates, flexible substrates are preferred since they can be lighter, thinner, more flexible and not easily crumbled. Therefore, flexible substrates are currently being applied in various applications, such as displaying devices, solar cells, energy-saving products, etc. Moreover, since flexible substrates can be built in a length reaching several thousand meters, it can be used in a continuous deposition process by the use of a roll-to-roll vacuum coating system. As the result, such roll-to-roll vacuum coating systems can be a vital tool for photonics industry and solar industry since it can be an effective means for increasing product yield, reducing manufacture cost and consequently enhancing product competitiveness. Therefore, in recent years, there are more and more resources being invested for developing better and more advanced roll-to-roll vacuum coating system.

However, it is possible to use various process gases in one continuous deposition process, no matter it is used for plasma pretreatment or for functional film deposition. Moreover, since generally in such continuous deposition process, substrates are being provided in a roll-to-roll manner, different process chambers in the continuous deposition process must be arranged interconnecting with one another. Thus, it is necessary to provide means to the continuous deposition process for isolating those process chambers from one another so as to prevent process gas in any one such process chamber from spreading into another process chambers and thus interacting other one another, causing great adverse effect to the quality of the resulting films. Moreover, if process chambers are not properly isolated from one another, the devices adapted for such continuous deposition process may not be able to function normally when different process chambers in the devices are performing different procedures of different vacuum pressures, such as a chemical vapor deposition (CVD) procedure and a physical vapor deposition (PVD) procedure. In addition, since for different film deposition procedures the substrate may be required to be heated to different temperatures and the substrate, especially those plastic substrates, may require to be cooled down after a deposition procedure for preventing the same from deformation, it is necessary for such roll-to-roll vacuum coating systems to have a mean with gas isolation and temperature buffering abilities.

### SUMMARY OF THE INVENTION

The primary object of the present invention is to provide a gas isolation chamber for preventing different process gases from spreading and mixing with one another so as to maintain the quality of a film deposited to reach a satisfactory purity.

Another object of the invention is to provide a plasma deposition apparatus adapted for a continuous deposition process that is capable of depositing various films on substrates using different deposition procedures as the substrates are continuously conveyed through the plasma deposition apparatus.

In an exemplary embodiment, the present invention provides a gas isolation chamber, comprising: a vacuum chamber, a first body module, a second body module, and a first temperature modulator. The vacuum chamber comprises a first chamber part, a second chamber part, and at least one first gas valve unit. The second chamber part is arranged corresponding to the first chamber part while allowing a first opening and a second opening to be formed between the first chamber part and the second chamber part. The at least one first gas valve unit is disposed on the first chamber part. The first body module is disposed on the inner wall of the first chamber part and has a first gas hole arranged at a position corresponding to the first gas valve unit while allowing the first gas hole to be connected to the first gas valve unit. The second body module is disposed on the inner wall of the second chamber part such that a slit channel can be formed between the second and the first body modules while allowing the slit channel to connected respectively to the first opening, the second opening and the first gas hole. The first temperature modulator is disposed in the first body module.

In another exemplary embodiment, the present invention provides a plasma deposition apparatus, comprising: a material feeding chamber, a first process chamber, a first gas isolation chamber, a second process chamber and a material collecting chamber. The first process chamber is connected to the material feeding chamber. The first gas isolation chamber is connected to the first process chamber and is composed of: a vacuum chamber, a first body module, a second body module and a first temperature modulator. The vacuum chamber comprises a first chamber part, a second chamber part and at least one first gas valve unit. The second chamber part is arranged corresponding to the first chamber part while allowing a first opening and a second opening to be formed between the first chamber part and the second chamber part. The at least one first gas valve unit is disposed on the first chamber part. The first body module is disposed on the inner wall of the first chamber part and has a first gas hole arranged at a position corresponding to the first gas valve unit while allowing the first gas hole to be connected to the first gas valve unit. The second body module is disposed on the inner wall of the second chamber part such that a slit channel can be formed between the second and the first body modules while allowing the slit to connected respectively to the first opening, the second opening and the first gas hole. The first temperature modulator is disposed in the first body module. The second process chamber is connected to the first gas isolation chamber. The material collecting chamber is connected to the second process chamber. The first gas isolation chamber is arranged at a position between the first process chamber and the second process chamber while allowing the first opening to connect to the first process chamber and the second opening to connect to the second process chamber.

Further scope of applicability of the present application will become more apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention and wherein:

FIG. 1A is a schematic diagram showing a heating-type gas isolation chamber according to a first embodiment of the present invention.

FIG. 1B is a schematic diagram showing a heating-type gas isolation chamber according to a second embodiment of the present invention.

FIG. 1C is a schematic diagram showing a cooling-type gas isolation chamber according to a third embodiment of the present invention.

FIG. 1D is a schematic diagram showing a cooling-type gas isolation chamber according to a fourth embodiment of the present invention.

FIG. 2 is a schematic diagram showing a roll-to-roll plasma deposition apparatus according to a fifth embodiment of the present invention.

FIG. 3 is a schematic diagram showing a roll-to-roll plasma deposition apparatus according to a sixth embodiment of the present invention.

FIG. 4 is a schematic diagram showing a roll-to-roll plasma deposition apparatus according to a seventh embodiment of the present invention.

FIG. 5 is a schematic diagram showing a roll-to-roll plasma deposition apparatus according to an eighth embodiment of the present invention.

### DESCRIPTION OF THE EXEMPLARY EMBODIMENTS

For your esteemed members of reviewing committee to further understand and recognize the fulfilled functions and structural characteristics of the invention, several exemplary embodiments cooperating with detailed description are presented as the follows.

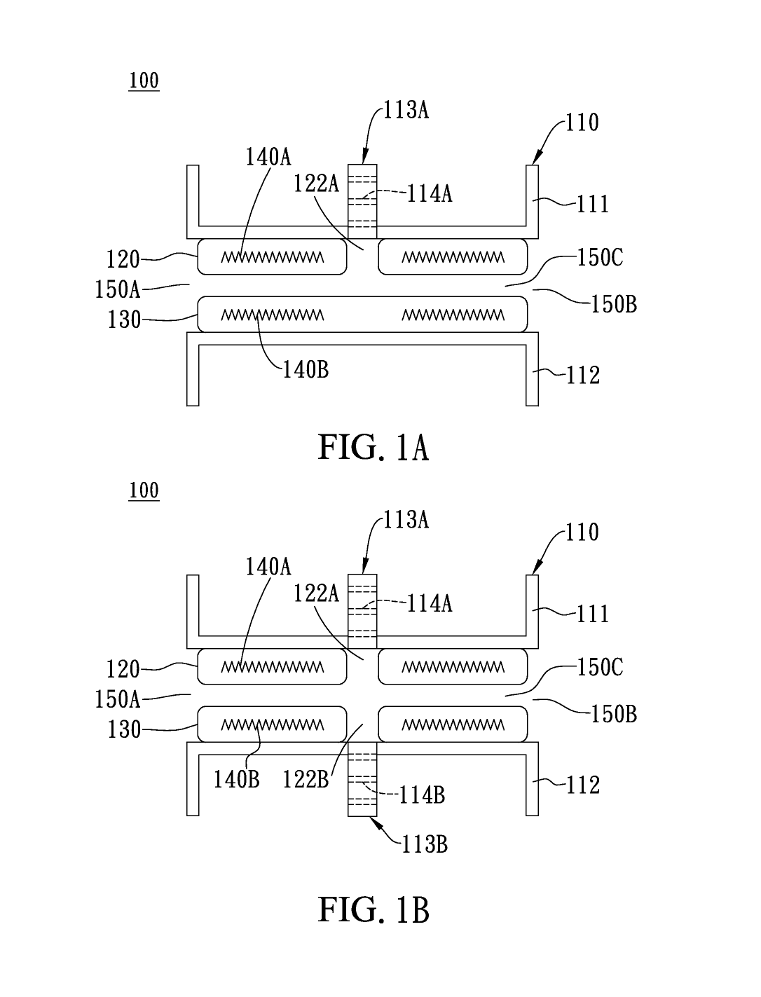

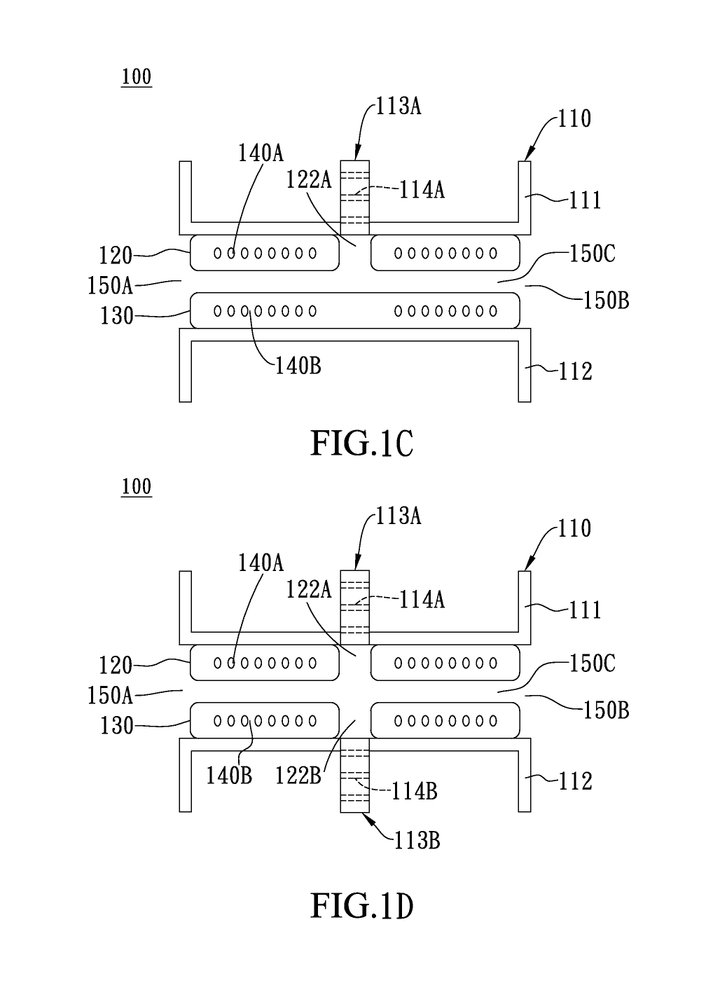

Please refer to FIG. 1A, which is a schematic diagram showing a heating-type gas isolation chamber according to a first embodiment of the present invention. In the first embodiment shown in FIG. 1A, the gas isolation chamber 100 comprises: a vacuum chamber 110, a first body module 120, a second body module 130, and a first temperature modulator 140A. The vacuum chamber 110 further comprises: a first chamber part 111, a second chamber part 112, and a first gas valve unit 113A. The second chamber part 112 is arranged corresponding to the first chamber part 111 while allowing a first opening 150A and a second opening 150B to be formed between the first chamber part 111 and the second chamber part 112. The first gas valve unit 113A is disposed on the first chamber part 111 and is further being configured with a first gas uniform distributor 114A for enabling a gas to be distributed evenly and uniformly. It is noted that although there is only one such first gas valve unit 113A used in this embodiment, it is not limited thereby and can be determined according to actual requirement. Therefore, it is possible to have a plurality of such first gas valve units 113A used in the gas isolation chamber 100.

The first body module 120 is disposed on the inner wall of the first chamber part 111 and has a first gas hole 122A arranged at a position corresponding to the first gas valve unit 113A while allowing the first gas hole 122A to be connected to the first gas valve unit 113A. The second body module 130 is disposed on the inner wall of the second chamber part 112 such that a slit channel 150C can be formed between the second and the first body modules 111, 112 while allowing the slit channel 150C to connected respectively to the first opening 150A, the second opening 150B and the first gas hole 122A. In addition, in another embodiment, the first body module 120 can be an integrally formed plate having a first gas hole 122A formed at a position corresponding to the first gas uniform distributor 114A.

The first temperature modulator 140A is disposed in the first body module 120. In this embodiment, the gas isolation chamber 100 further has a second temperature modulator 140B, which is disposed inside the second body module 130. It is noted that either the first temperature modulator 140A or the second temperature modulator 140B can be a heating strip, or a device composed of a plurality of heating tubes, but is not limited thereby and can be any device capable of regulating the internal temperature of the gas isolation chamber 100. During the performing of a manufacturing process, gases like inert gases or process gases are enabled to flow through the first gas valve unit 113A inside the gas isolation chamber 100 so as to be distributed evenly by the first gas uniform distributor 114A to flow into the first gas hole 122A of the first body module 120. Thereafter, the gas flowing through the first gas hole 122A will flow into the clit channel 150C between the first body module 120 and the second body module 130, and since the silt channel 150C is designed with high gas resistance, the gas flow will be stopped and thus the two process chambers that is separated by the gas isolation chamber 100 will not be in gas communication with each other. Simultaneously, by the use of either the first temperature modulator 140A or the second temperature modulator 140B, the substrate in the silt channel 150C can be heated. In this embodiment, the substrate that is adapted to be used in the gas isolation chamber 100 can be all kinds of flexible substrates, such as polyethylene terephthalate (PET) substrates, polyimide (PI) substrates, polycarbonate (PC) substrates, plastic substrates, or metal foil substrates.

Please refer to FIG. 1B, which is a schematic diagram showing a heating-type gas isolation chamber according to a second embodiment of the present invention. In this second embodiment, the vacuum chamber 110 of gas isolation chamber 100 further has a second gas valve unit 113B that is disposed on the second chamber part 112, and also there is further a second gas hole 122B formed on the second body module 130 at a position thereof corresponding to the second gas hole 122B while allowing the second gas hole 122B to be in gas communication with the second gas valve unit 113B, and consequently, the slit channel 150C is arranged for enabling the same to be connected respectively to the first opening 150A, the second opening 150B, the first gas hole 122A and the second gas hole 122B. In addition, the second gas valve unit 113B further has a second gas uniform distributor 114B. It is noted that the operation principle as well the material of the substrate used in this second embodiment are the same those described in the first embodiment, and thus will not be described further herein. Similarly, although there is only one such second gas valve unit 113B used in this second embodiment, it is not limited thereby and can be determined according to actual requirement. Therefore, it is possible to have a plurality of such second gas valve units 113B used in the gas isolation chamber 100.

Please refer to FIG. 1C, which is a schematic diagram showing a cooling-type gas isolation chamber according to a third embodiment of the present invention. The third embodiment shown in FIG. 1C is a variation of the heating-type gas isolation chamber of the first embodiment. In this third embodiment, each of the first and the second temperature modulators 140A and 140B is a device composed of a plurality of cooling tubes, but they are not limited thereby. Other than that the operation principle as well the material of the substrate used in this second embodiment are the same those described in the first embodiment, and thus will not be described further herein.

Please refer to FIG. 1D, which is a schematic diagram showing a cooling-type gas isolation chamber according to a fourth embodiment of the present invention. The fourth embodiment shown in FIG. 1D is a variation of the heating-type gas isolation chamber of the second embodiment. In this fourth embodiment, each of the first and the second temperature modulators 140A and 140B is a device composed of a plurality of cooling tubes, but they are not limited thereby. Other than that the operation principle as well the material of the substrate used in this second embodiment are the same those described in the second embodiment, and thus will not be described further herein. In addition, although there is only one such second gas valve unit 113B used in this fourth embodiment, it is not limited thereby and can be determined according to actual requirement. Therefore, it is possible to have a plurality of such second gas valve units 113B used in the gas isolation chamber 100.

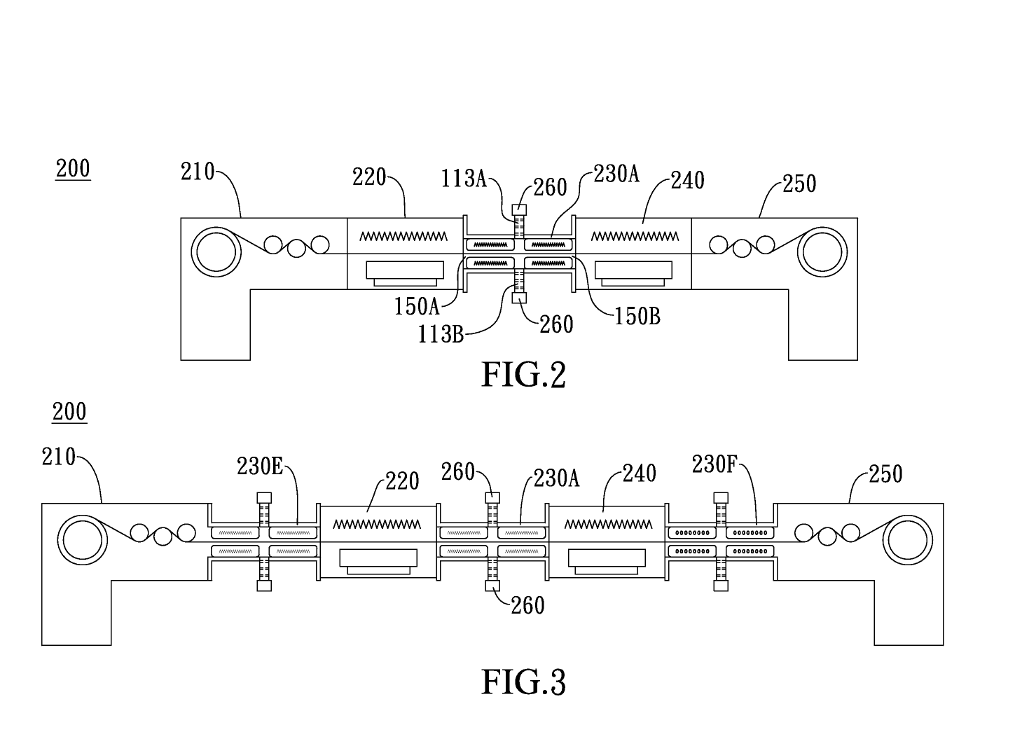

Please refer to FIG. 2, which is a schematic diagram showing a roll-to-roll plasma deposition apparatus according to a fifth embodiment of the present invention. As shown in FIG. 2, the roll-to-roll plasma deposition apparatus 200 comprises: a material feeding chamber 210, a first process chamber 220, a first gas isolation chamber 230A, a second process chamber 240 and a material collecting chamber 250. The first process chamber 220 is connected to the material feeding chamber 210. The first gas isolation chamber 230A is connected to the first process chamber 220 and the second process chamber 240 respectively by the two sides thereof for allowing the first gas isolation chamber 230A to be sandwiched between the first process chamber 220 and the second process chamber 240. In addition, in this fifth embodiment, the first opening 150A of the first gas isolation chamber 230A is connected to the first process chamber 220, while allowing the second opening 150B to be connected to the second process chamber 240. It is noted that the first gas isolation chamber 230A in this fifth embodiment can be the gas isolation chamber selected from the first, the second, the third and the fourth embodiments of the present invention, and in this fifth embodiment, it is selected to be the gas isolation chamber 230A shown in FIG, 1B for illustration. The material collecting chamber 250 is connected to the second process chamber 240. In addition, each of the first and the second process chambers 220, 240 is enabled to perform a process selected from the group consisting: a plasma-enhanced chemical vapor deposition (PECVD) process, a physical vapor deposition (PVD) process, other plasma-enhanced deposition processes, a pretreatment process of plasma-enhanced chemical vapor deposition (PECVD), a pretreatment process of physical vapor deposition (PVD), and other plasma-enhanced pretreatment processes, but is not limited thereby.

In this fifth embodiment, the plasma deposition apparatus 200 further comprises a plurality of gas supplying systems 260, whereas the plural gas supplying systems 260 are respectively connected to their corresponding first gas valve unit 113A and second gas valve unit 113B. Moreover, other than the embodiment shown in FIG. 2, the plasma deposition apparatus can be configured with one additional gas isolation chamber that us structured the same as the first gas isolation chamber 230A, whereas this additional gas isolation chamber can be disposed at a position between the material feeding chamber 210 and the first process chamber 220 while connecting respectively to the two chambers in one embodiment, or can be disposed at a position between the second process chamber and the material collecting chamber 250 while connecting respectively to the two chambers in another embodiment.

Please refer to FIG. 3, which is a schematic diagram showing a roll-to-roll plasma deposition apparatus according to a sixth embodiment of the present invention. In this six embodiment, the plasma deposition apparatus 200 further comprises: a fifth gas isolation chamber 230E and a sixth gas isolation chamber 230F, that are both structured the same as the first gas isolation chamber 230A, whereas the fifth gas isolation chamber 230E is sandwiched between the material feeding chamber 210 and the first process chamber 220 while connecting to the two chambers, and the sixth gas isolation chamber 230F is sandwiched between the second process chamber 240 and the material collecting chamber 250 while connecting to the two chambers. Similarly, the gas isolation chamber can be arranged at a position between different process chambers, and the amount of gas valve unit in one gas isolation chamber as well as the amount of the process chamber can be determined according to actual requirement, and the sequencing in a manufacturing process can be altered at will. In a continuous vacuum multi-layered film deposition process, different process gases in different process chambers can be isolated from spreading by the use of gas isolation chambers so as to maintain the quality of a film deposited to reach a satisfactory purity, and thus, such multi-layered film deposition process can be adapted to form semiconductor elements directly on a substrate, such as p/i/n silicon thin-film solar cells.

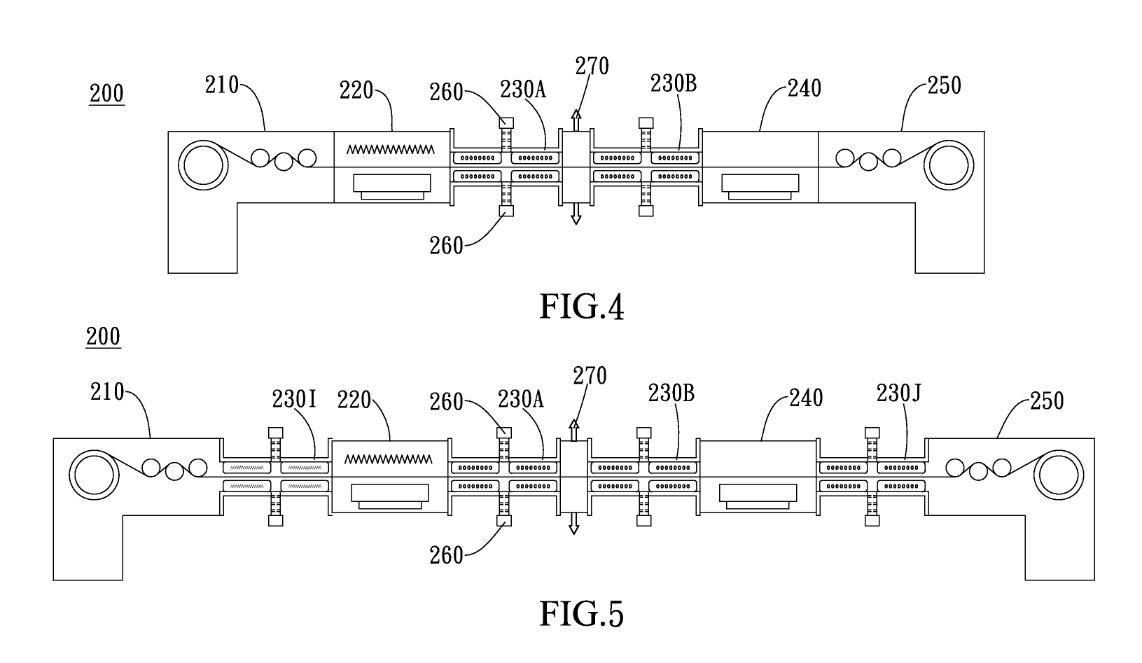

Please refer to FIG. 4, which is a schematic diagram showing a roll-to-roll plasma deposition apparatus according to a seventh embodiment of the present invention. In this seventh embodiment, the plasma deposition apparatus 200 further comprises: a buffer pump 270 and a second gas isolation chamber 230B that is structured the same as the first gas isolation chamber 230A. The buffer pump 270 and the second gas isolation chamber 230B are disposed respectively at positions between the first gas isolation chamber 230A and the second process chamber 240 while allowing the buffer pump 270 to connect to the first gas isolation chamber 230A, and the second gas isolation chamber 230B to connect to the second process chamber 240. Moreover, in addition to the configuration shown in FIG. 4, the plasma deposition apparatus can further have an additional gas isolation chamber that is also structured the same as the first and the second gas isolation chambers 230A and 230B. In one embodiment, the additional gas isolation chamber can be disposed at a position between the material feeding chamber 210 and the first process chamber 220 while connecting to the two chambers. Nevertheless, in another embodiment, the additional gas isolation chamber can be disposed at a position between the second process chamber 240 and the material collecting chamber 250 while connecting to the two chambers.

Please refer to FIG. 5, which is a schematic diagram showing a roll-to-roll plasma deposition apparatus according to a eighth embodiment of the present invention. In this eighth embodiment, the plasma deposition apparatus 200 further comprises: a ninth gas isolation chamber 2301 and a tenth gas isolation chamber 230J, that are both structured the same as the first gas isolation chamber 230A, whereas the ninth gas isolation chamber 2301 is sandwiched between the material feeding chamber 210 and the first process chamber 220 while connecting to the two chambers, and the tenth gas isolation chamber 230J is sandwiched between the second process chamber 240 and the material collecting chamber 250 while connecting to the two chambers. Similarly, the gas isolation chamber can be arranged at a position between different process chambers, and the amount of gas valve unit in one gas isolation chamber as well as the amount of the process chamber can be determined according to actual requirement, and the sequencing in a manufacturing process can be altered at will. Moreover, in the seventh embodiment and the eighth embodiment, the first process chamber 220 is used for enabling a PVD pretreatment process while the second process chamber 240 is used for enabling a PVD process, but is not limited thereby. It is noted that the pressure difference between the PVD pretreatment process and the PVD process is more than two orders of magnitude. Consequently, the two gas isolation chambers 230A and 230B and the buffer pump 270 are used in order to achieve a satisfactory isolation effect, in which as the gas supplying system 260 is used for feeding gases, such as argon or other process gases, the buffer pump 270 is used to create different gas pressures between different process chambers for assisting isolation. Operationally, the first process chamber 220 is used for enabling a degassing and surface activation process upon a polymer substrate, and the polymer substrate is cooled down by the cooling-type gas isolation chambers 230A, 230B, and the second process chamber 240 is used for depositing an ITO film or an optic multi-layered film on the substrate to be used as a touch control film for instance.

To sum up, a plasma deposition apparatus of the present invention can be composed of several gas isolation chambers and process chambers for adapting the same to a continuous deposition process that is capable of depositing various films on substrates using different deposition procedures as the substrates are continuously conveyed through the plasma deposition apparatus, and thereby, the plasma deposition apparatus of the present invention can be an effective means for increasing product yield, reducing manufacture cost and consequently enhancing product competitiveness.

Operationally, the gas isolation chamber of the present invention not only can be used for isolating different process gases in different process chambers from spreading so as to maintain the quality of a film deposited to reach a satisfactory purity in a continuous deposition process, but also is able to heat and maintain the temperature of the substrate at constant which enable the device for the continuous deposition process to have shorter preheating units and also enable the quality of the resulting deposited film to be improved.

For those polymer substrates that are low in heat tolerance, the heating strip in the gas isolation chamber of the present invention can be replaced by cooling tubes, by that the gas isolation chamber not only is able to isolate different process gases in different process chambers and the moisture released from the polymer substrate from spreading, but also the temperature of the polymer substrate can be reduced properly for preventing the same from deformation.

With respect to the above description then, it is to be realized that the optimum dimensional relationships for the parts of the invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention.

What is claimed is:

1. A gas isolation chamber, comprising:
a vacuum chamber, further comprising:
a first chamber part;
a second chamber part, arranged corresponding to the first chamber part while allowing a first opening and a second opening to be formed between the first chamber part and the second chamber part; and
at least one first gas valve unit, disposed on the first chamber part;
a first body module, disposed on the inner wall of the first chamber part, having a first gas hole arranged at a position corresponding to the at least one first gas valve unit while allowing the first gas hole to be connected to the at least one first gas valve unit;
a second body module, disposed on the inner wall of the second chamber part at a position corresponding to the first body part for allowing a slit channel to be formed between the second and the first body modules in a manner that the slit channel is connected respectively to the first opening, the second opening and the first gas hole; and
a first temperature modulator, disposed in the first body module.

2. The gas isolation chamber of claim 1, wherein each of the at least one first gas valve unit further comprises: a first gas uniform distributor.

3. The gas isolation chamber of claim 1, wherein the vacuum chamber further comprises at least one second gas valve unit, and the at least one second gas valve unit is disposed on the second chamber part.

4. The gas isolation chamber of claim 3, wherein the second body module further has a second gas hole arranged at a position corresponding to the at least one second gas valve unit while allowing the second gas hole to be connected to the at least one second gas valve unit.

5. The gas isolation chamber of claim 4, wherein the slit channel is connected respectively to the first opening, the second opening and the second gas hole.

6. The gas isolation chamber of claim 1, further comprising:
a second temperature modulator, disposed on the second body module.

7. The gas isolation chamber of claim 3, wherein each of the second valve unit further comprises: a second gas uniform distributor.

8. The gas isolation chamber of claim 6, wherein each of the first and the second temperature modulator is a device selected from the group consisting of: a heating strip, a device composed of a plurality of heating tubes, and a device composed of a plurality of cooling tubes.

9. A plasma deposition apparatus, comprising:
a material feeding chamber;
a first process chamber, connected to the material feeding chamber;
a first gas isolation chamber, further comprising:
a vacuum chamber, further comprising:
a first chamber part;
a second chamber part, arranged corresponding to the first chamber part while allowing a first opening and a second opening to be formed between the first chamber part and the second chamber part; and
at least one first gas valve unit, disposed on the first chamber part;
a first body module, disposed on the inner wall of the first chamber part, having a first gas hole arranged at a position corresponding to the at least one first gas valve unit while allowing the first gas hole to be connected to the at least one first gas valve unit
a second body module, disposed on the inner wall of the second chamber part at a position corresponding to the first body part for allowing a slit channel to be formed between the second and the first body modules in a manner that the slit channel is connected respectively to the first opening, the second opening and the first gas hole; and
a first temperature modulator, disposed in the first body module;
a second process chamber, connected to the first gas isolation chamber; and
a material collecting chamber, connected to the second process chamber;
wherein, the first gas isolation chamber is arranged at a position between the first process chamber and the second process chamber while allowing the first opening to connect to the first process chamber and the second opening to connect to the second process chamber.

10. The plasma deposition apparatus of claim 9, wherein each of the at least one first gas valve unit further comprises: a first gas uniform distributor.

11. The plasma deposition apparatus of claim 9, wherein the vacuum chamber further comprises at least one second gas valve unit, and the at least one second gas valve unit is disposed on the second chamber part.

12. The plasma deposition apparatus of claim 11, wherein the second body module further has a second gas hole arranged at a position corresponding to the at least one second gas valve unit while allowing the second gas hole to be connected to the at least one second gas valve unit.

13. The plasma deposition apparatus of claim 12, wherein the slit channel is connected respectively to the first opening, the second opening and the second gas hole.

14. The plasma deposition apparatus of claim 9, further comprising:
a second temperature modulator, disposed on the second body module.

15. The plasma deposition apparatus of claim 11, wherein each of the second valve unit further comprises: a second gas uniform distributor.

16. The plasma deposition apparatus of claim 14, wherein each of the first and the second temperature modulators is a device selected from the group consisting of: a heating strip, a device composed of a plurality of heating tubes, and a device composed of a plurality of cooling tubes.

17. The plasma deposition apparatus of claim 9, wherein each of the first and the second process chambers is enabled to perform a process selected from the group consisting: a plasma-enhanced chemical vapor deposition (PECVD) process, a physical vapor deposition (PVD) process, and other plasma-enhanced deposition processes.

18. The plasma deposition apparatus of claim 9, wherein each of the first and the second process chambers is enabled to perform a process selected from the group consisting: a pretreatment process of plasma-enhanced chemical vapor deposition (PECVD), a pretreatment process of physical vapor deposition (PVD), and other plasma-enhanced pretreatment processes.

19. The plasma deposition apparatus of claim 11, further comprises:
a plurality of gas supplying systems, respectively connected to their corresponding first gas valve unit and second gas valve unit.

20. The plasma deposition apparatus of claim 9, further comprising:
a buffer pump; and
a second gas isolation chamber, structured the same as the first gas isolation chamber;
wherein, the buffer pump and the second gas isolation chamber are disposed at a position between the first gas isolation chamber and the second process chamber while allowing the buffer pump to connected to the first gas isolation chamber and the second gas isolation chamber to connected respectively to the buffer pump and the second process chamber.

21. The plasma deposition apparatus of claim 9, further comprising:
a third gas isolation chamber, structured the same as the first gas isolation chamber, disposed at a position between the material feeding chamber and the first process chamber while allowing the third gas isolation chamber to connected respectively to the material feeding chamber and the first process chamber.

22. The plasma deposition apparatus of claim 20, further comprising:
a third gas isolation chamber, structured the same as the first gas isolation chamber, disposed at a position between the material feeding chamber and the first process chamber while allowing the third gas isolation chamber to connected respectively to the material feeding chamber and the first process chamber.

23. The plasma deposition apparatus of claim 9, further comprising:
a fourth gas isolation chamber, structured the same as the first gas isolation chamber, disposed at a position between the second process chamber and the material collecting chamber while allowing the fourth gas isolation chamber to connected respectively to the second process chamber and the material collecting chamber.

24. The plasma deposition apparatus of claim 20, further comprising:
a fourth gas isolation chamber, structured the same as the first gas isolation chamber, disposed at a position between the second process chamber and the material collecting chamber while allowing the fourth gas isolation chamber to connected respectively to the second process chamber and the material collecting chamber.

25. The plasma deposition apparatus of claim 9, further comprising:
a fifth gas isolation chamber, structured the same as the first gas isolation chamber, disposed at a position between the material feeding chamber and the first process chamber while allowing the fifth gas isolation chamber to connected respectively to the material feeding chamber and the first process chamber; and
a sixth gas isolation chamber, structured the same as the first gas isolation chamber, disposed at a position between the second process chamber and the material collecting chamber while allowing the sixth gas isolation chamber to connected respectively to the second process chamber and the material collecting chamber.

26. The plasma deposition apparatus of claim 20, further comprising:
a fifth gas isolation chamber, structured the same as the first gas isolation chamber, disposed at a position between the material feeding chamber and the first process chamber while allowing the fifth gas isolation chamber to connected respectively to the material feeding chamber and the first process chamber; and
a sixth gas isolation chamber, structured the same as the first gas isolation chamber, disposed at a position between the second process chamber and the material collecting chamber while allowing the sixth gas isolation chamber to connected respectively to the second process chamber and the material collecting chamber.
